(19) United States
(12) Patent Application Publication
(10) Pub. No.: US 2003/0075745 A1
(43) Pub. Date: Apr. 24, 2003

(54) Semiconductor integrated circuit, MOS transistor, semicoductor device, robot and management system of lottery

(75) Inventors: Shigenobu Maeda, Tokyo (JP); Koichiro Mashiko, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: MITSUBISHI DENKI KABUSHIKI KAISHA, TOKYO (JP)

(21) Appl. No.: 10/138,569

(22) Filed: May 6, 2002

(30) Foreign Application Priority Data
Oct. 22, 2001 (JP) 2001-323164

(51) Int. Cl. H01L 29/76

(52) U.S. Cl. 257/288

(57) ABSTRACT

As a first semiconductor element and a second semiconductor element, provided are two p-type MOS transistors (11a, 11b) for forming an element pair (11). These MOS transistors (11a, 11b) are compared with each other in electronic characteristic and a result of which is utilized for determining binary logic for the element pair (11). These MOS transistors (11a, 11b) are integrated and hence, they are equally subjected to ambient temperature. As a result, the result of comparison therebetween in electronic characteristic is unlikely to be subjected to ambient temperature.

### BACKGROUND OF THE INVENTION

1. Field of the Invention

The present invention relates to a technique of utilizing state unique to a semiconductor element as an identification code of a device including such semiconductor element mounted thereon.

2. Description of the Background Art

There has been an unauthorized act of changing one's own identification code and disguising oneself as another person in a communication network. In order to prevent such unauthorized act, there has been a technique of storing unique identification code in an information terminal used in the communication network. A program for controlling operation of the information terminal may be changed to be compliant with a new communication system. Therefore, the program has been stored in a rewritable storage medium such as a flash memory which further stores an identification code. Namely, the identification code stored in the recording medium has also been rewritable from the outside, resulting in insufficient prevention of occurrence of the foregoing unauthorized act.

In view of this, a technique has been developed utilizing state unique to a semiconductor element has been developed to assign unique identification code to the information terminal. This technique utilizes the fact that the electronic characteristic of a semiconductor element such as a thin film transistor including polycrystalline semiconductor depends on the crystal structure thereof. Such electronic characteristic is converted into an identification code which is then to be used to a device including this semiconductor element mounted thereon. The technique described here is introduced in Japanese Patent Application Laid-Open No. 2001-7290 filed in the name of MITSUBISHI DENKI KABUSHIKI KAISHA, for example.

FIG. 18 is a circuit diagram illustrating arrangement of semiconductor elements introduced in Japanese Patent Application Laid-Open No. 2001-7290. Thin film transistors 101 each including polycrystalline semiconductor are arranged in a matrix with 4 rows and 4 columns, for example. Further, a plurality of word lines WL1 through WL4 and a plurality of bit lines BL1 through BL4 are provided to extend in a direction of row (lateral direction in the plane of the drawing) and in a direction of column (longitudinal direction in the plane of the drawing), respectively.

The word lines WL1 through WL4 each have connection to their respective gate electrodes of four thin film transistors 101 arranged in the direction of row commonly connected thereto. Further, the bit lines BL1 through BL4 each have connection to their respective drain electrodes of four thin film transistors 101 arranged in the direction of column commonly connected thereto. A total of 16 thin film transistors 101 include source electrodes each bearing the same positive potential Vcc applied thereto. The bit lines BL1 through BIL4 each have one end grounded through a bit line load 17.

The bit line load 17 has an end opposite to the ground end thereof for establishing connection to an interconnect line 18 to be connected to a sense amplifier not shown. Further, the bit lines BL1 through BL4 each have the other end connected to a pad 15 and the word lines WL1 through WL4 each have one end connected to a pad 16.

When a gate voltage at a prescribed level is applied to a selected one of the word lines WL1 through WI4, drain currents Id1 through Id4 flow in four thin film transistors 101 connected to the selected word line. The drain currents Id1 through Id4 flow through separate bit line loads 17 and therefore, the interconnect lines 18 connected to the bit lines BL1 through BL4 bear their respective potentials developed therein that are proportionate to the drain currents Id1 through Id4. By sequentially applying the gate voltage to the word lines WL1 through WL4, a total of 16 potentials can be taken out.

Together with a reference potential, the potentials thereby applied to the interconnect lines 18 are applied to the respective sense amplifiers. The sense amplifier compares the reference potential and the potential at the interconnect line 18. The result of the comparison, namely, binary logic indicating whether the potential at the interconnect line 18 is higher or lower than the reference potential constitutes an identification code. The binary logic thereby obtained reflects the crystal structure of the polycrystalline semiconductor as a material for each thin film transistor 101. When one reference potential is fixed at a certain level, a 16-bit identification code is obtained accordingly on the basis of variation in characteristic among the 16 thin film transistors 101.

However, a drain current is generally determined according to gate voltage and ambient temperature. An identification code to be obtained on the basis of the drain current as described above may also be dependent on gate voltage and ambient temperature. In contrast to this, an identification code should desirably be unique to an information terminal.

### SUMMARY OF THE INVENTION

It is therefore a first object of the present invention to provide a technique for generating an identification code that is unlikely to be subjected to gate voltage and ambient temperature.

It is a second object of the present invention to suggest the structure of a semiconductor element for facilitating generation of an identification code that randomly varies.

It is a third object of the present invention to suggest application of a device utilizing an identification code.

According to the present invention, a semiconductor integrated circuit includes a plurality of element pairs each including a first semiconductor element and a second semiconductor element. The first semiconductor element and the second semiconductor element are compared in electronic characteristic and a result of which is utilized for determining a binary logic for each of the plurality of element pairs.

Utilizing the binary logic determined for each element pair, an identification code unique to a semiconductor device can be obtained. As the first and the second semiconductor elements are integrated, they are equally subjected to ambient temperature. The result of comparison therebetween in electronic characteristic is hence unlikely to be subjected to ambient temperature. As a result, the binary logic determined for each element pair and eventually, the identification code uniquely obtained for the semiconductor integrated circuit are also unlikely to be subjected to ambient temperature.

According to the present invention, a MOS transistor includes a gate electrode, a gate insulating film and a polycrystalline semiconductor layer. The gate electrode has a planarized main surface. The polycrystalline semiconductor layer has a channel region, a source region and a drain region. The polycrystalline semiconductor layer is opposed to the gate electrode through the gate insulating film with an area smaller than that of the main surface.

The surface of the polycrystalline semiconductor layer opposed to the planarized main surface is also planarized. The regularity in crystal structure resulting from the existence of a step defined by the gate electrode is thereby avoided in the polycrystalline semiconductor layer, easily causing variation in crystal structure thereof. As a result, the MOS transistor is preferably utilized for obtaining a unique identification code based on the electronic characteristic thereof.

A MOS transistor of the present invention has a source region, a drain region and a channel region including polycrystalline semiconductor. In the MOS transistor, at least one of a channel width and a channel length of the channel region has a value that is not less than the same as and not more than 10 times an average value of a diameter of a crystal grain in the polycrystalline semiconductor.

A crystal grain may be entirely included in the channel region with high probability, thereby providing high probability of existence of crystal grain boundary therein. As a result, the MOS transistor is preferably utilized for obtaining a unique identification code based on the electronic characteristic thereof.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a circuit diagram illustrating the structure of a semiconductor integrated circuit according to a first preferred embodiment of the present invention;

FIG. 2 is a plan view illustrating the exemplary structure of a thin film transistor applicable to the present invention;

FIG. 3 is a cross-sectional view taken along a cutting plane line A-A in FIG. 2;

FIG. 4 is a graph showing dependence of drain current on ambient temperature;

FIG. 5 is a graph showing dependence of drain current on gate voltage;

FIG. 6 is a cross-sectional view illustrating the exemplary structure of a semiconductor device according to a second preferred embodiment of the present invention;

FIG. 7 is a plan view illustrating regions A1 and A2 defined in FIG. 6;

FIGS. 8 and 9 are cross-sectional views each illustrating the exemplary steps for providing a thin film transistor following sequence thereof;

FIGS. 10 and 11 are graphs each showing frequency distribution of the length of crystal grain boundary;

FIG. 12 is a conceptual view schematically illustrating a fourth preferred embodiment of the present invention;

FIG. 13 is a conceptual view schematically illustrating a fifth preferred embodiment of the present invention;

FIGS. 14 and 15 are conceptual views each schematically illustrating a sixth preferred embodiment of the present invention;

FIGS. 16 and 17 are conceptual views each schematically illustrating a seventh preferred embodiment of the present invention; and

FIG. 18 is a circuit diagram illustrating technique in the background art.

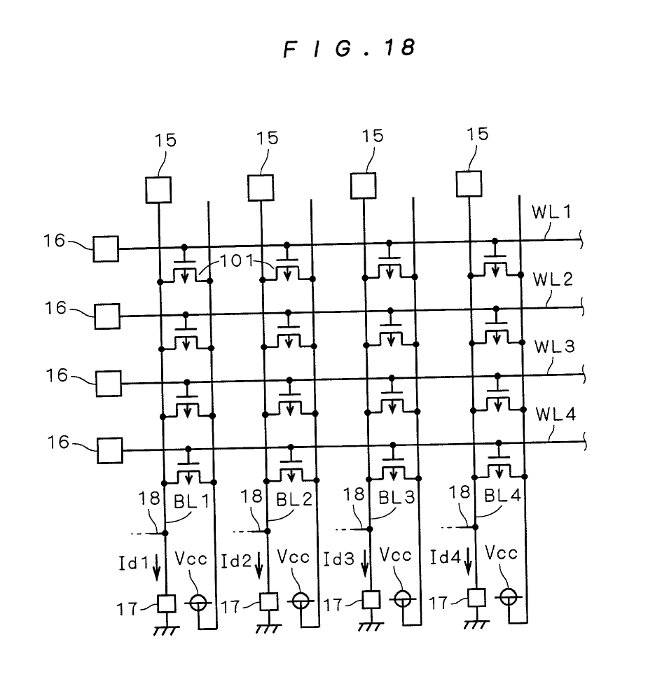

### DESCRIPTION OF THE PREFERRED EMBODIMENTS

First Preferred Embodiment

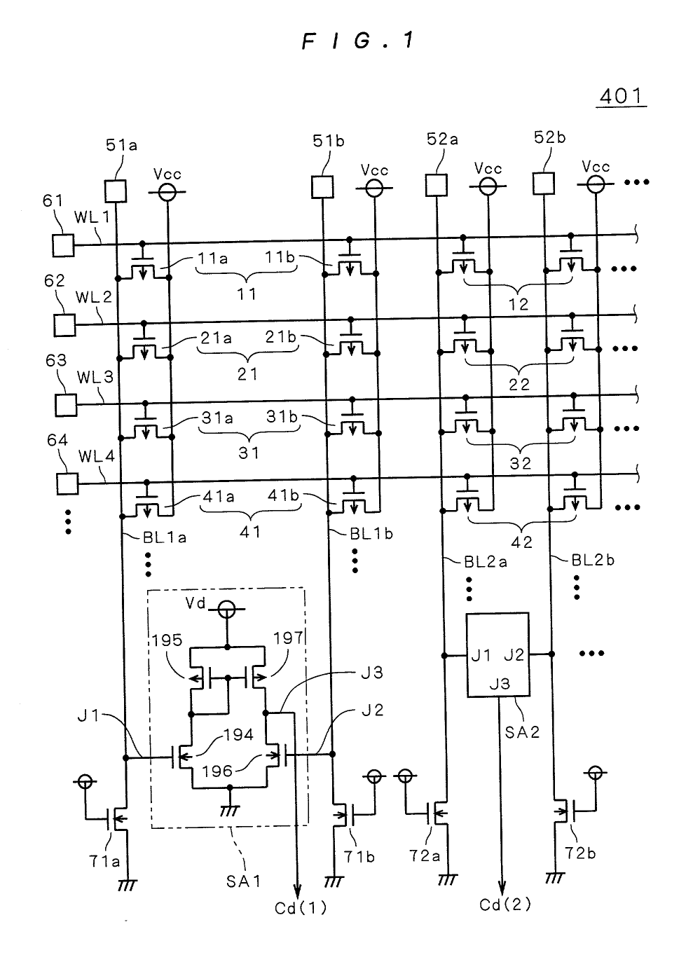

FIG. 1 is a circuit diagram illustrating the structure of a semiconductor integrated circuit according to the first preferred embodiment of the present invention. P-type MOS transistors 11a, 21, 31a, 41a, . . . and p-type MOS transistors 11b, 21b, 31b, 41b, are provided as first semiconductor elements and second semiconductor elements, respectively. The MOS transistors 11a and 11b form an element pair 11, 21a and 21b form an element pair 21, 31a and 31b form an element pair 31 and 41a and 41b form an element pair 41. Similar to the element pairs 11, 21, 31, 41, . . . , further provided are element pairs 12, 22, 32, 42, . . . each including a first semiconductor element and a second semiconductor element.

According to the present invention, the electronic characteristics of the first and second semiconductor elements are compared and the result of which is a determinant of binary logic of each element pair. As the first and second semiconductor elements are integrated, they are equally subjected to ambient temperature. The result of comparison therebetween in electronic characteristic is hence unlikely to be subjected to ambient temperature.

The first preferred embodiment utilizes characteristic of a drain current of a MOS transistor relative to a gate potential of the same (hereinafter referred to as “drain current characteristic”). The drain current characteristic is generally sensitive to the structure of the MOS transistor and therefore, may be preferably utilized as the basis for the comparison between the first and second semiconductor elements to determine binary logic.

For comparison in drain current characteristic, respective source electrodes of the MOS transistors 11a, 21a, 31a, 41a, . . . and 11b, 21b, 31b, 41b, . . . receive the same fixed potential (for example, a positive potential Vcc) applied thereto. A first bit line BL1a connected to each drain electrode of the MOS transistors 11a, 21a, 31a, 41a, . . . and a second bit line BL1b connected to each drain electrode of the MOS transistors 11b, 21b, 31b, 41b, . . . are provided. Similar to the element pairs 11, 21, 31, 41, . . . , the element pairs 12, 22, 32, 42, . . . have their respective connections to a first bit line BL2a and a second bit line BL2b. Further, respective source electrodes of the MOS transistors for forming the element pairs 12, 22, 32, 42, . . . receive the same positive potential Vcc applied thereto.

The first bit lines BL1a, BL2a, . . . are grounded through loads 71a, 72a, respectively. The second bit lines BL1b, BL2b, . . . are grounded through loads 71b, 72b, . . . , respectively. In FIG. 1, the loads 71a, 72a, 71b and 72b are exemplified as n-type MOS transistors including respective grounded source electrodes, fixed gate potentials and drain electrodes respectively connected to the bit lines BL1a, BL2a, BL1b and BL2b. Similar to the background art, pads 51a, 51b, 52a, 52b, . . . may be provided to one end of the bit lines BL1a, BL2a, BL1b, BL2b, . . . in this order.

A first input terminal J1 and a second input terminal J2 of an sense amplifier SA1 are respectively connected to a node of the first bit line BL1a and the load 71a, and to a node of the second bit line BL1b and the load 71b. Further, first and second input terminals of a sense amplifier SA2 are connected to a node of the first bit line BL2a and the load 72a and to a node of the second bit line BL2b and the load 72b, respectively.

The sense amplifiers SA1, SA2, . . . may be of the same circuit configuration. FIG. 1 illustrates the exemplary configuration of the sense amplifier SA1. The sense amplifier SA1 includes a series circuit having an n-type MOS transistor 194 and a p-type MOS transistor 195, and a series circuit having an n-type MOS transistor 196 and a p-type MOS transistor 197. These circuits are interposed between a ground and a positive power source Vd. Gate and drain electrodes of the MOS transistor 195 and a gate electrode of the MOS transistor 197 are connected to each other, thereby forming a current mirror circuit. Further, gate electrodes of the MOS transistors 194 and 196 are respectively connected to the first and second input terminals J1 and J2. The inequality between the first and second bit lines BL1a and BL1b in magnitude of current flowing therethrough is thereby outputted as a binary logic Cd(1) of the potential at a node J3 of the MOS transistors 196 and 197.

A word line WL1 is provided correspondingly to the element pairs 11, 12, . . . to be connected to each gate electrode of the MOS transistors for forming these element pairs. Similarly, word lines WL2, WL3 and WL4 are provided correspondingly to the element pairs 21, 22, . . . , 31, 32, . . . and 41, 42, . . . , respectively. Further, pads 61, 62, 63, 64, . . . may be provided to one end of the word lines WL1, WL2, WL3, WL4, . . . in this order as in the background art.

A predetermined potential is applied to the selected one of the word lines WL1, WL2, WL3, WL4, . . . thereby determining binary logic such as Cd(1) and Cd(2) from the respective element pairs 11, 12, and so forth. The binary logics Cd(1), Cd(2), . . . may differ according to the result of selection from the word lines. Namely, binary logics obtained per sense amplifier differ among the word lines.

As to be described later, when two separate MOS transistors receive the same source potential and gate potential each applied thereto, inequality in magnitude of drain current given between these transistors is unlikely to be subjected to the magnitude of source potential and gate potential. As a result, binary logic is also unlikely to be subjected to variation in potential to be applied to the word line.

The first preferred embodiment thereby allow generation of an identification code having little probability of influence of ambient temperature and potential at the word line.

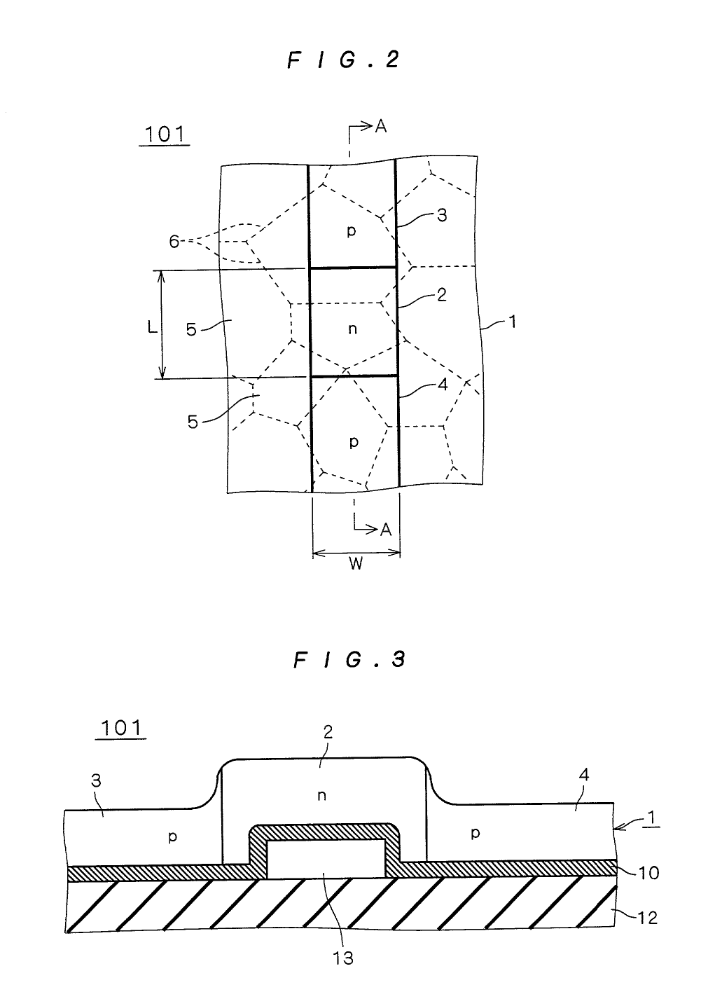

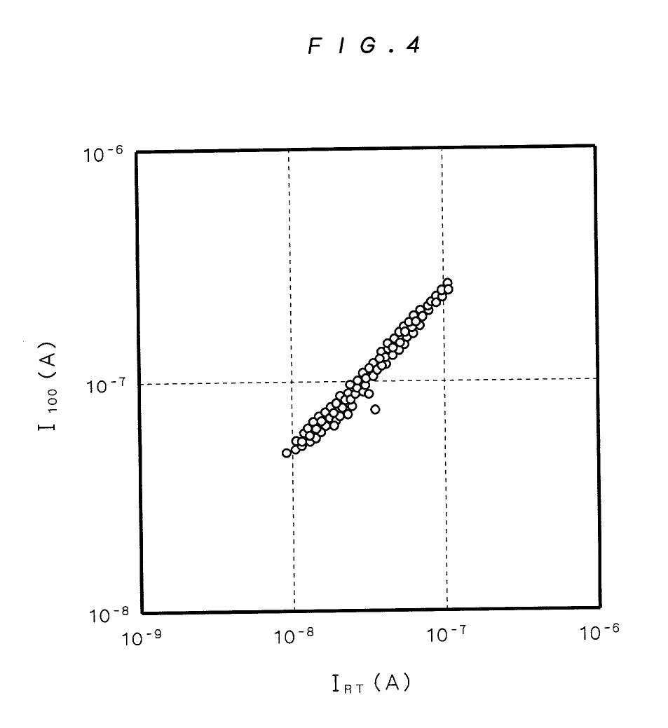

A thin film transistor including polycrystalline semiconductor may be applicable as the MOS transistor such as 11a, 21a, 31a, 41a and 11b, 21b, 31b, 41b . FIG. 2 is a plan view illustrating the exemplary structure of a thin film transistor 101 applicable to the present invention. FIG. 3 is a cross-sectional view taken along the cutting plane line A-A in FIG. 2. The thin film transistor 101 includes polycrystalline semiconductor at least in a channel region thereof.

The thin film transistor 101 has an insulating film 12 and a gate electrode 13 selectively provided thereon. The surfaces of the insulating film 12 and the gate electrode 13 are entirely covered with an insulating film 10. Also provided on the insulating film 10 is a semiconductor layer 1. The exemplary material of each element is as follows. That is, the insulating film 12 includes silicon oxide, the gate electrode 13 includes polysilicon doped with impurities, the insulating film 10 includes silicon oxide such as TEOS and the semiconductor layer 1 mainly includes silicon.

The semiconductor layer 1 includes a channel region 2 arranged above the gate electrode 13 and source, drain regions 3, 4 for holding the channel region 2 interposed therebetween. The portion of the insulating film 10 having contact with the channel region 2 serves as a gate insulating film. The exemplary thin film transistor 101 in the first preferred embodiment is a p-type MOS transistor. Therefore, the channel region 2 has an n-type conductivity while the source and drain regions 3 and 4 each have a p-type conductivity. It is a matter of course that an n-type MOS transistor is also applicable to the present invention.

The semiconductor layer 1 is a polycrystalline semiconductor layer including a plurality of crystal grains 5 and crystal grain boundaries 6 each defined in a boundary surface between adjacent crystal grains. A single crystal grain 5 has a uniform crystal orientation while separate crystal grains 5 generally have their respective orientations. Further, the crystal grains 5 randomly differ thereamong in dimension and location. As a result, while a number of thin film transistors 101 may be identical in macroscopic structure, they are likely to randomly differ thereamong in crystal structure of the semiconductor layer 1, namely, in microscopic structure thereof. The thin film transistor including polycrystalline semiconductor is generally known to possess characteristic that is to vary according to the amount of crystal grains included in the channel region (as introduced in IEEE Transactions on Electron Devices, Vol. 45, No. 1, January (1998), pp. 165-172, for example). In light of this, utilizing the thin film transistor 101 as the MOS transistor such as 11a, 21a, 31a, 41a and 11b, 21b, 31b, 41b, an identification code can be obtained that randomly differs from one semiconductor integrated circuit to another.

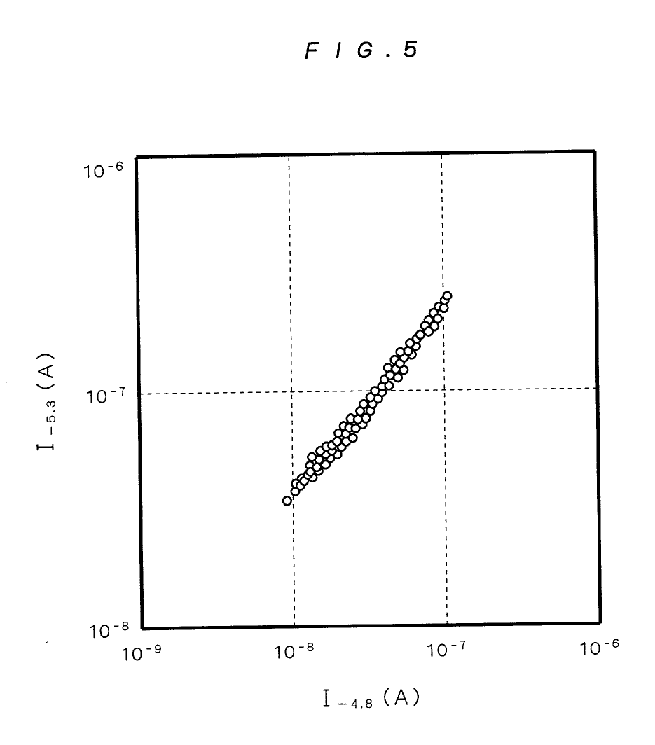

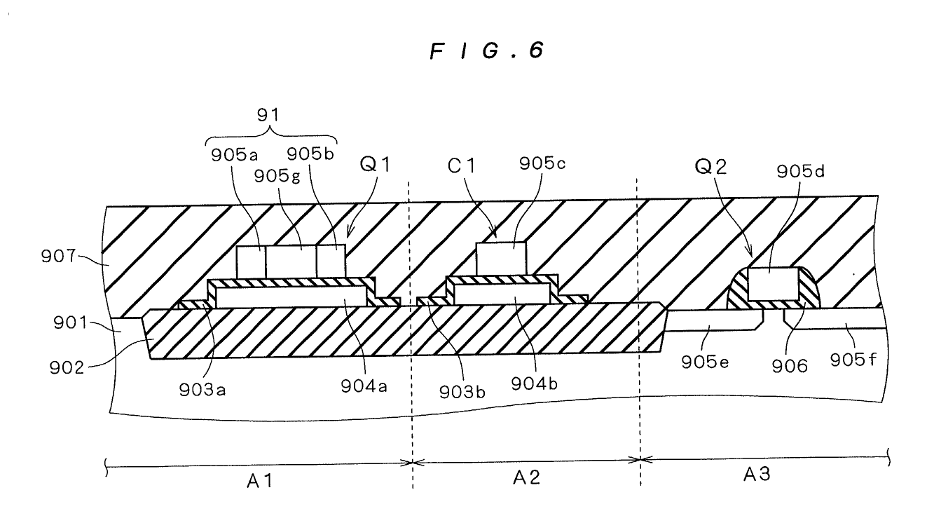

FIGS. 4 and 5 are graphs respectively showing dependence of drain current on ambient temperature and on gate potential, provided by measurement results obtained from a number of thin film transistors 101.

In FIG. 4, the horizontal axis indicates magnitude of a drain current I_{RT} at a room temperature while the vertical axis indicates that of a drain current I₁₀₀ at a temperature of 100° C. More particularly, for each of the drain currents I_{RT} and I₁₀₀, drain and gate potential are respectively set at −1.8 V and −4.8 V relative to a source potential. As shown in this graph, there is a definitely positive correlation between the currents I_{RT} and I₁₀₀. In view of this, it is seen that the result of comparison in drain current between two separate thin film transistors 101 (namely, the result indicating which transistor receives higher current) is unlikely to be subjected to ambient temperature.

In FIG. 5, the horizontal axis indicates magnitude of a drain current L_{4.8} with a gate potential of −4.8 V while the vertical axis indicates that of a drain current L_{5.3} with a gate potential of −5.3 V. More particularly, for each of the drain currents L_{4.8} and L_{5.3}, a drain potential is set at −1.8 V relative to a source potential. As shown in this graph, there is a definitely positive correlation between the currents L_{4.8} and L_{5.3}. In view of this, it is seen that the result of comparison in drain current between two separate thin. film transistors 101 (namely, the result indicating which transistor receives higher current) is unlikely to be subjected to gate potential and eventually, unlikely to be subjected to potential at word line.

The thin film transistor 101 may alternatively have channel region 2 solely including polycrystalline semiconductor and source, drain regions 3, 4 each including single-crystalline semiconductor, possibly resulting in increase in complexity of the manufacturing steps. In this case, drain current characteristic also randomly varies.

The type of the semiconductor element to be applied as the MOS transistor such as 11a, 21a, 31a, 41a and 11b, 21b, 31b, 41b is not limited to a thin film transistor including polycrystalline semiconductor having a tendency to randomly vary in microscopic structure from one transistor to another. Even when the transistors have the identical macroscopic structure, each transistor may acquire unique characteristic defined by the chemical structure of semiconductor such as variation in impurity concentration. Such unique characteristic will be utilized for identification (as introduced in K. Lofstrom, et al., Tech. Dig. ISSCC, p. 3272 (2000), for example). As a result, by applying transistor to the present invention generating an impurity concentration that randomly varies from one transistor to another, an identification code having little probability of influence of ambient temperature and potential at word line can be obtained.

Regardless of whether binary logic is obtained on the basis of difference in microscopic structure such as crystal structure or difference in chemical structure such as impurity concentration, semiconductor elements to be employed as the first and second semiconductor elements should desirably be identical in macroscopic structure. This is because dependence of electronic characteristic on the shape of the semiconductor element is reduced and further, microscopic and chemical structure may be likely to randomly vary even when the elements are to be manufactured following the same steps. As a result, binary logic and eventually, an identification code is preferably obtained on the basis of such microscopic and chemical structure. The identicalness between the elements in macroscopic structure includes not only the concept of isomorphism but also covers the concept of mirror image. For example, when one semiconductor element includes the rectangular channel region 2 in plan view defined by a channel width W and a channel length L (see FIG. 2) having the same dimensions as those for defining the channel region 2 in another one, these semiconductor elements may be defined to be identical in macroscopic structure at least relative to the channel region 2.

The technique of generating identification code described in the first preferred embodiment may be apparently applicable to the various techniques utilizing identification code as introduced in Japanese Patent Application Laid-Open No. 2001-7290. And further, such application can be easily realized.

Second Preferred Embodiment

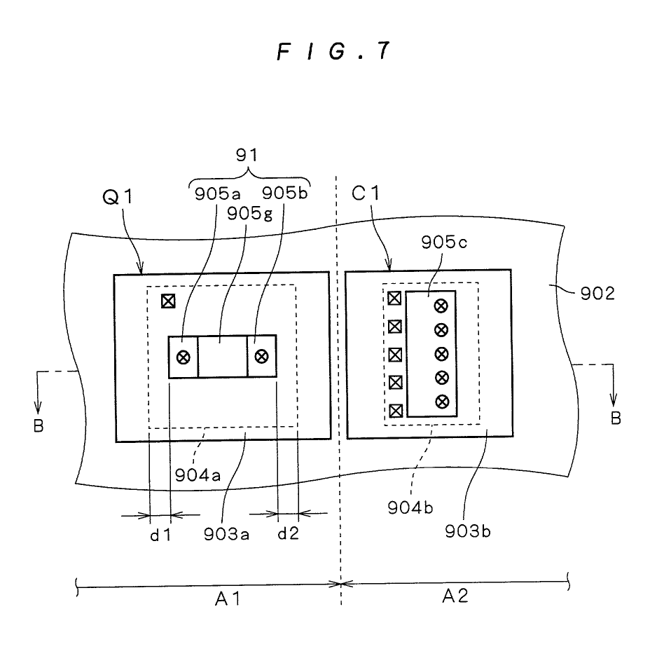

FIG. 6 is a cross-sectional view illustrating the exemplary structure of a semiconductor device according to the second preferred embodiment of the present invention. A semiconductor substrate 901 is divided into regions A1, A2 and A3 including a thin film transistor Q1, a capacitor C1 and a MOS transistor Q2, respectively. In the region A3, impurity regions 905e and 905f are selectively provided in the surface of the semiconductor substrate 901 to be spaced apart from each other. The regions 905e and 905f each serve as either one of source/drain regions of the transistor Q2. A gate electrode 905d is provided at a position opposed to that defined between the impurity regions 905e and 905f in the surface of the semiconductor substrate 901. Together with the sidewalls of the gate electrode 905d, a gate insulating film interposed between the gate electrode 905d and the semiconductor substrate 901 form an insulator 906.

The regions A1 and A2 includes an insulating film 902 for element isolation in the surface of the semiconductor substrate 901. The thin film transistor Q1 and the capacitor C1 are provided on the insulating film 902 for element isolation.

The region A1 includes a gate electrode 904a selectively provided on the insulating film 902 for element isolation. The main surface of the gate electrode 904a, namely, the surface opposite to the semiconductor substrate 901 is planarized. An insulating film 903a covers the main surface, side surfaces of the gate electrode 904a and the outer periphery of the side surfaces thereof, thereby partially covering the insulating film 902 for element isolation. A polycrystalline semiconductor layer 91 is opposed to the gate electrode 904a through the insulating film 903a with an area smaller than that of the main surface of the gate electrode 904a. The polycrystalline semiconductor layer 91 includes a channel region 905g, a source region 905a and a drain region 905b. The insulating film 903a serves as a gate insulating film of the transistor Q1.

The region A2 includes a lower electrode 904b selectively provided on the insulating film 902 for element isolation. An insulating film 903b covers the main surface, side surfaces of the lower electrode 904b and the outer periphery of the side surfaces thereof, thereby partially covering the insulating film 902 for element isolation. An upper electrode 905c is opposed to the lower electrode 904b through the insulating film 903b with an area smaller than that of the main surface of the lower electrode 904b.

The regions A1, A2 and A3 are provided with an interlayer insulating film 907 for covering the transistor Q1, Q2 and the capacitor C1.

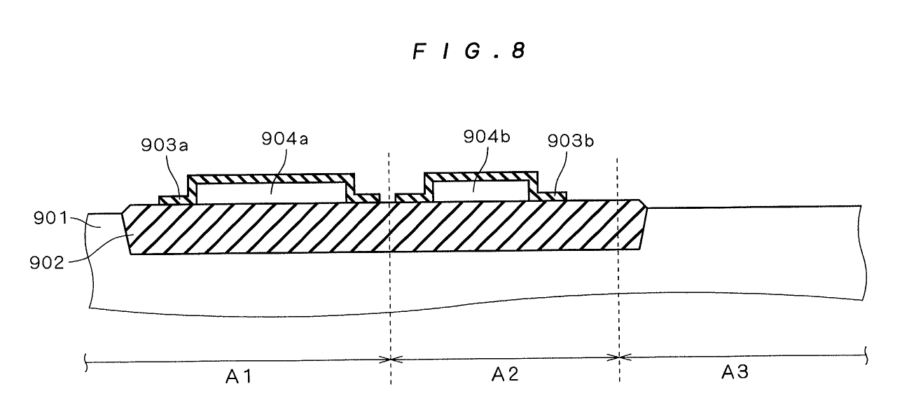

FIG. 7 is a plan view illustrating the regions A1 and A2 defined in FIG. 6 omitting illustration of the interlayer insulating film 907. The regions A1 and A2 are illustratively shown in cross section in FIG. 6 taken along a cutting plane line B-B defined in FIG. 7. In FIG. 7, crosses surrounded by squares designate contact holes penetrating the insulating film 903a or 903b and crosses surrounded by circles designate contact holes penetrating the interlayer insulating film 907.

The polycrystalline semiconductor layer 91 is opposed to the gate electrode 904a with an area smaller than that of the main surface of the gate electrode 904a. Therefore, the edges of the source region 905a and the drain region 905b are apart from those of the gate electrode 904a at distances d1 and d2, respectively. In other words, the polycrystalline semiconductor layer 91 dose not reach steps defined by the main surface and the side surfaces of the gate electrode 904a. The regularity in crystal structure resulting from the existence of such step is thereby avoided in the polycrystalline semiconductor layer 91, easily causing variation in crystal structure thereof. For this reason, the thin film transistor Q1 is preferably utilized for obtaining a unique identification code according to the electronic characteristic thereof. Further preferably, the thin film transistor Q1 is further preferably applied to the first preferred embodiment as well as to the various techniques introduced in Japanese Patent Application Laid-Open No. 2001-7290.

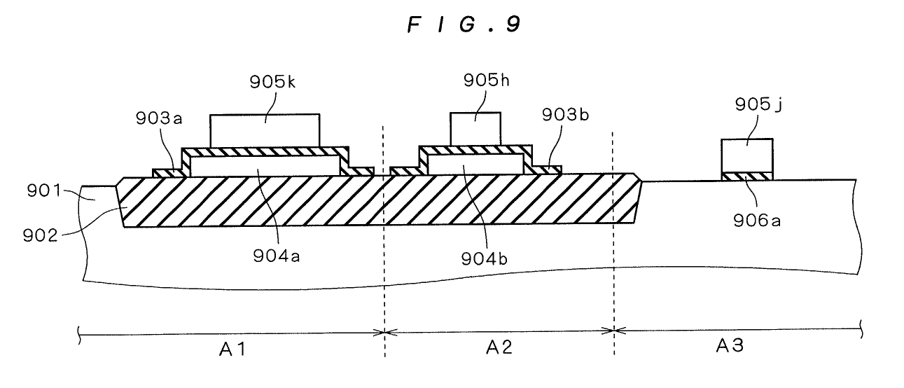

FIGS. 8 and 9 are cross-sectional views each illustrating the exemplary steps of providing the thin film transistor Q1 along with the steps of providing the capacitor C1 and the MOS transistor Q2 following the sequence thereof. With reference to FIG. 8, in the regions A1 and A2, the insulating film 902 for element isolation is provided in the surface of the semiconductor substrate 901. Next, the gate electrode 904a and the lower electrode 904b are respectively provided in the regions A1 and A2. More particularly, polycrystalline silicon is deposited to entirely cover the surfaces of the insulating film 902 for element isolation and the semiconductor substrate 901, for example. After being doped with impurities, this polycrystalline silicon bears conductivity. This polycrystalline silicon is then selectively etched using a lithography technique, thereby forming the gate electrode 904a and the lower electrode 904b.

The insulating films 903a and 903b are thereafter provided. More particularly, a silicon oxide film is deposited to cover the surfaces of the gate electrode 904a, the lower electrode 904b, the insulating film 902 for element isolation and the semiconductor substrate 901, for example. This silicon oxide film is then selectively etched using a lithography technique, thereby forming the insulating films 903a and 903b. Following these steps described so far, the structure illustrated in FIG. 8 is obtained.

With reference to FIG. 9, after providing a gate insulating film 906a in the region A3, polycrystalline semiconductor layers 905k, 905h and 905j are respectively provided on the insulating films 903a, 903b and the gate insulating film 906a. The dimension of the polycrystalline semiconductor layer 905k is smaller than that of the gate electrode 904a in plan view. More particularly, polycrystalline silicon is deposited to cover the surfaces of the insulating films 903a, 903b, the gate insulating film 906a, the insulating film 902 for element isolation and the semiconductor substrate 901, for example. This polycrystalline silicon is then selectively etched using a lithography technique, thereby forming the polycrystalline semiconductor layers 905k, 905h and 905j. Following these steps described so far, the structure illustrated in FIG. 9 is obtained.

Thereafter the polycrystalline semiconductor layers 905k, 905h and 905j are doped with impurities using a patterned resist as a mask, thereby forming the polycrystalline semiconductor layer 91, the upper electrode 905c and the gate electrode 905d, respectively. Also provided are the sidewalls of the MOS transistor Q2 and the interlayer insulating film 907, thereby completing the structure illustrated in FIG. 6.

The foregoing steps for forming the capacitor C1 are publicly known and may be used for facilitating formation of the thin film transistor Q1 according to the second preferred embodiment.

Third Preferred Embodiment

According to the disclosure in Japanese Patent Application Laid-Open No. 2001-7290, by defining an average value d of diameter of crystal grain, the channel length L and the channel width W, range of variation in characteristic of the thin film transistor 101 is shown to be extended. More particularly, in view of the fact that variation in drain current characteristic of the thin film transistor 101 is determined on the basis of variation in amount of crystal grain boundaries 6 defined in the channel region 2, Japanese Patent Application Laid-Open No. 2001-7290 is directed to extend range of variation in amount of the crystal grain boundaries 6 in the channel region 2. When the values of the channel length L and the channel width W are each equal to the average value d of diameter of crystal grain, the drain current characteristic is shown to be most likely to vary. It is further shown that for practical use, each value of the channel length L and the channel width W desirably ranges between 0.5 and 10 times the average value d of diameter of crystal grain, thereby increasing availability.

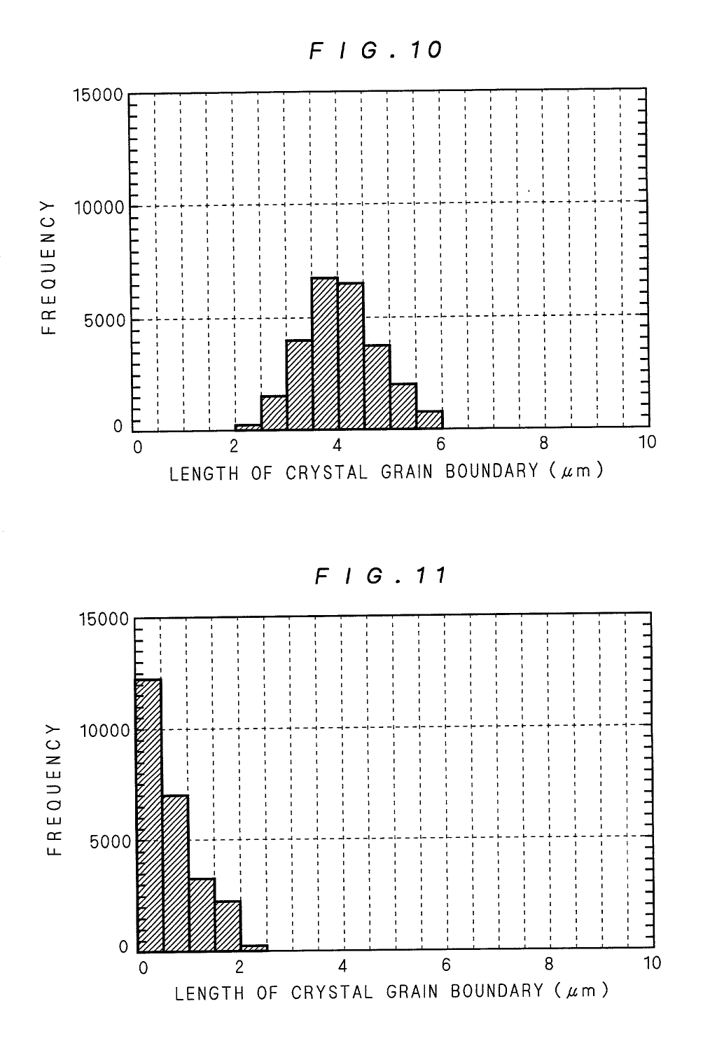

The third preferred embodiment further suggests desirable relation among these values from a different point of view. FIGS. 10 and 11 are graphs each showing frequency distribution of the length of crystal grain boundary with the channel length L of 1.2 ì m and the channel width W of 0.6 ì m. Further, the results have been graphed with the average value d of diameter of crystal grain that are 0.48 ì m and 3.2 ì m in FIGS. 10 and 11, respectively.

In FIG. 10, the distribution of the length of crystal grain boundary is shown in an almost Gaussian curve. In contrast, the distribution of the same is concentrated in rather small values in FIG. 11. Hence, it is obviously known that polycrystalline semiconductor exhibiting distribution shown in FIG. 10 is desirably utilized, thereby obtaining semiconductor element allowing providing binary logic that randomly varies.

With reference to FIG. 2, the difference in distribution of the length of crystal grain between FIGS. 10 and 11 may result from a large difference therebetween in probability of existence of crystal grain boundary in the channel region 2. When the average value d of diameter of crystal grain is smaller than the size of the channel region 2 (as shown in FIG. 10), a crystal grain may be entirely included in the channel region 2 with high probability, thereby providing high probability of existence of crystal grain boundary therein. In contrast, when the average value d of diameter of crystal grain is larger than the size of the channel region 2 (as shown in FIG. 11), the probability of existence of crystal grain boundary in the channel region 2 will be considerably small.

From this point of view, it is seen that the channel length L and the channel width W are each desired to have a value not less than average value d of diameter of crystal grain. In consideration of the foregoing relation provided by Japanese Patent Application Laid-Open No. 2001-7290, further, it is also seen that the channel length L and the channel width W are each desired to have a value that is not less than the same as and not more than 10 times the average value d of diameter of crystal grain.

Fourth Preferred Embodiment

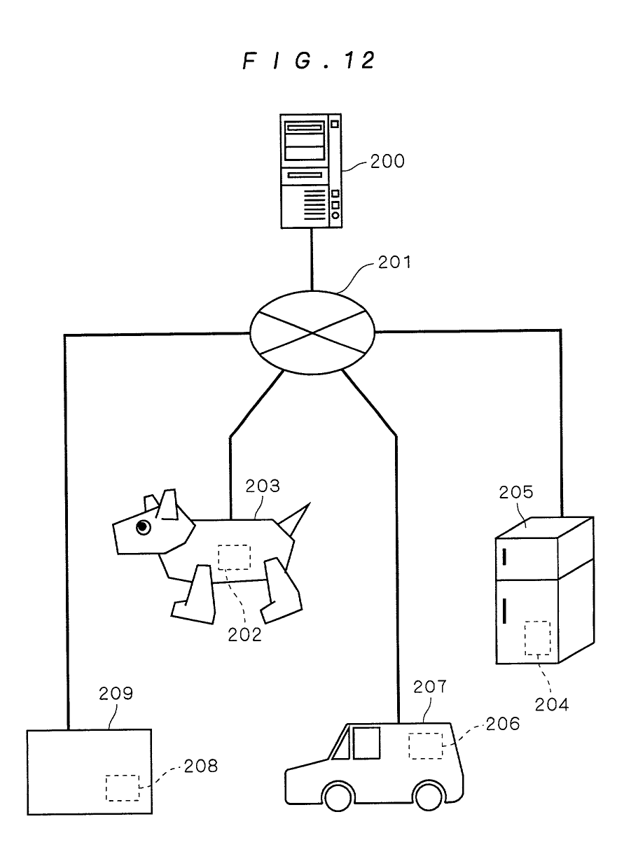

FIG. 12 is a conceptual view schematically illustrating the fourth preferred embodiment of the present invention. As described in Japanese Patent Application Laid-Open No. 2001-7290 or in the first through third preferred embodiments of the present invention, state unique to a semiconductor element can be utilized for assigning a unique identification code to an information terminal. Therefore, the information terminal including such semiconductor element mounted thereon is allowed to transmit its own identification code, thereby informing a destination of its access thereto. It is possible accordingly to keep track of the access condition from the information terminal. Further, as the information terminal utilizes the identification code resulting from the state unique to the semiconductor element therein, it is difficult to commit an unauthorized act of changing one's own identification code and disguising oneself as another person using such information terminal.

For example, a robot and more particularly, a pet-type robot 203 is provided with a semiconductor element 202 having a unique identification code. The identification code in the semiconductor element 202 is transmitted through a communication network 201, thereby notifying a server 200 for constructing the network 201 of the access from the pet-type robot 203. Similarly, a home electrical appliance and more particularly, a refrigerator 205 is provided with a semiconductor element 204 having a unique identification code. A mobile unit and more particularly, an automobile 207 and a card 209 are respectively provided with semiconductor elements 206 and 208 each having a unique identification code. The identification codes included in the semiconductor elements 204, 206 and 208 are transmitted through the communication network 201, thereby notifying the server 200 for constructing the network 201 of the access from the refrigerator 205, from the automobile 207 and from the card 209, respectively.

Fifth Preferred Embodiment

As described above, state unique to a semiconductor element can be utilized as a unique identification code. As a result, a semiconductor device including such semiconductor element mounted thereon and eventually, a robot including such semiconductor device may be operable according to the identification code unique thereto, thereby developing individuality of the robot.

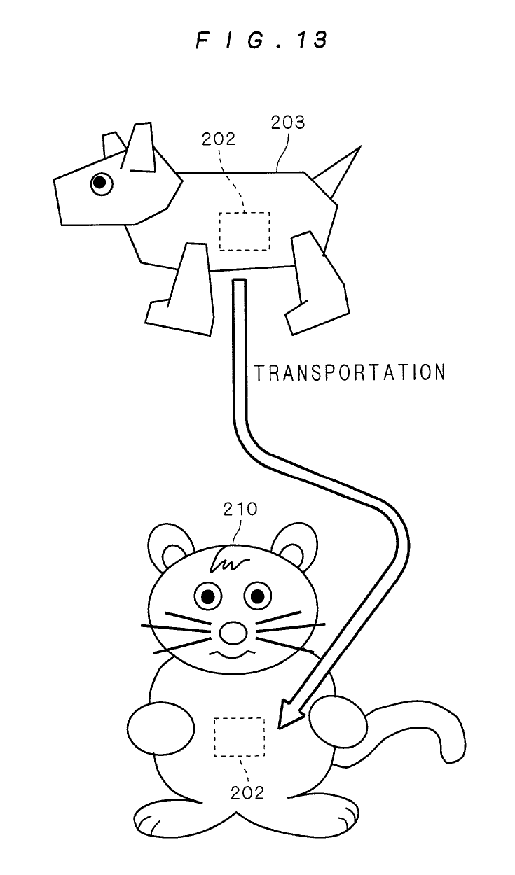

FIG. 13 is a conceptual view schematically illustrating the fifth preferred embodiment of the present invention. According to the specific bit value of the identification code defined by the semiconductor element 202, it is allowed to vary raising speed of the exemplary pet-type robot 203 including the semiconductor element 202 and define handedness of the same. Such individuality is preferable for increasing affection, especially in the pet-type robot.

Further, such individuality of the robot can be a kind of inheritance to another robot. If there occurs breakdown in some part in the pet-type robot 203 other than the semiconductor element 202, the semiconductor element 202 can be transported to a new pet-type robot 210. The pet-type robot 210 is thereby allowed to inherit individuality from the pet-type robot 203.

Sixth Preferred Embodiment

As described above, state unique to a semiconductor element can be utilized as a unique identification code. As a result, a semiconductor device including such semiconductor element mounted thereon and eventually, a game machine including such semiconductor device may be operable according to random numbers defined on the basis of the unique identification code, thereby enhancing enjoyment in playing a game.

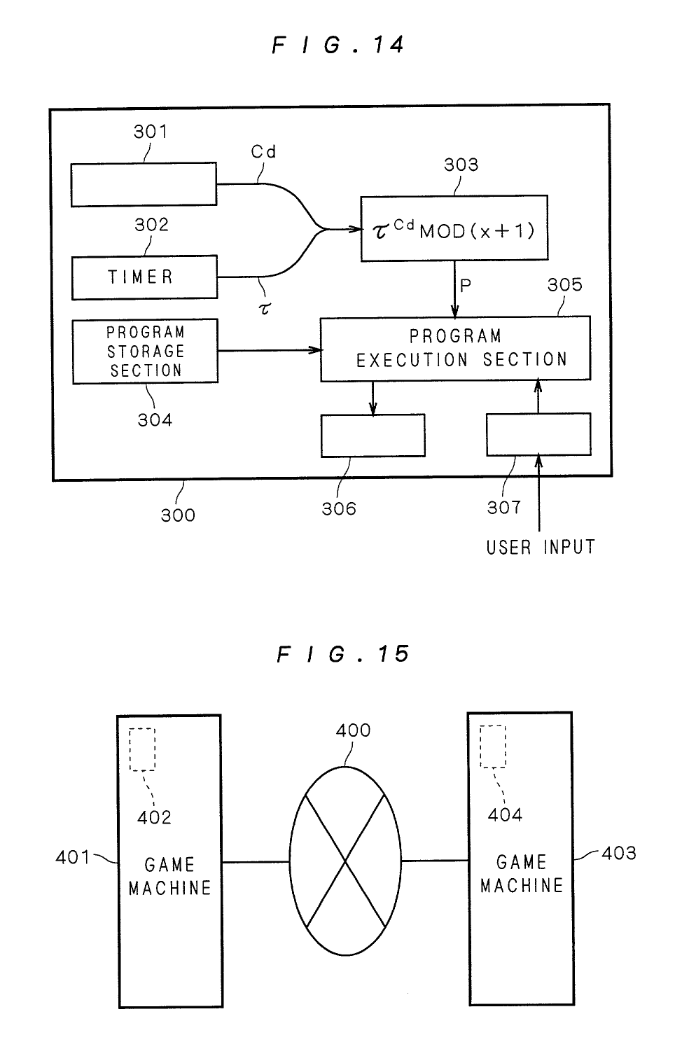

FIG. 14 is a conceptual view schematically illustrating the sixth preferred embodiment of the present invention. A game machine 300 includes a semiconductor element 301 for providing a unique identification code Cd, a timer 302 for giving present time τ, a random number generator 303 for generating random numbers P on the basis of the identification code Cd and the present time τ, a game program storage section 304 for storing a game program and a program execution section 305 for executing a program developed according to the random numbers P and facilitating a game. While these sections are independently illustrated in FIG. 14, they may be integral as a single semiconductor device. Further included in the game machine 300 are an output section 306 and an input section 307.

The random number generator 303 divides τ^{Cd} by (x+1) to determine remainders thereof as the random numbers P. The random numbers relative to 0 through x are thereby determined. Naturally, the random numbers P may be obtained by the alternative calculation as long as the calculation is based on the identification code Cd.

Based on the random numbers P thereby obtained, a game program is executed and a game proceeds. Therefore, a wide range of variation of the game can be enjoyed. A user is allowed to handle the game from the input section 307 while recognizing progress of the game notified from the output section 306.

FIG. 15 is a conceptual view schematically illustrating the sixth preferred embodiment of the present invention in another phase. Game machines 401 and 403 are respectively provided with semiconductor elements 402 and 404 each having a unique identification code. The game machines 401 and 403 are communicatively coupled to each other through a communication network 400. Using the game machines 401 and 403, a competing game can be enjoyed.

In the competing game, identification codes of both players are compared to obtain result of the game.

A competing game guessing identification code of a competitor may be also enjoyed. In this game, one expects the content of one bit of the competitor's identification code and based on the correctness of the expectation, one is allowed to guess the competitor's identification code.

Seventh Preferred Embodiment

Utilizing randomness of a unique identification code provided by a semiconductor element, a management system of lottery will be suggested.

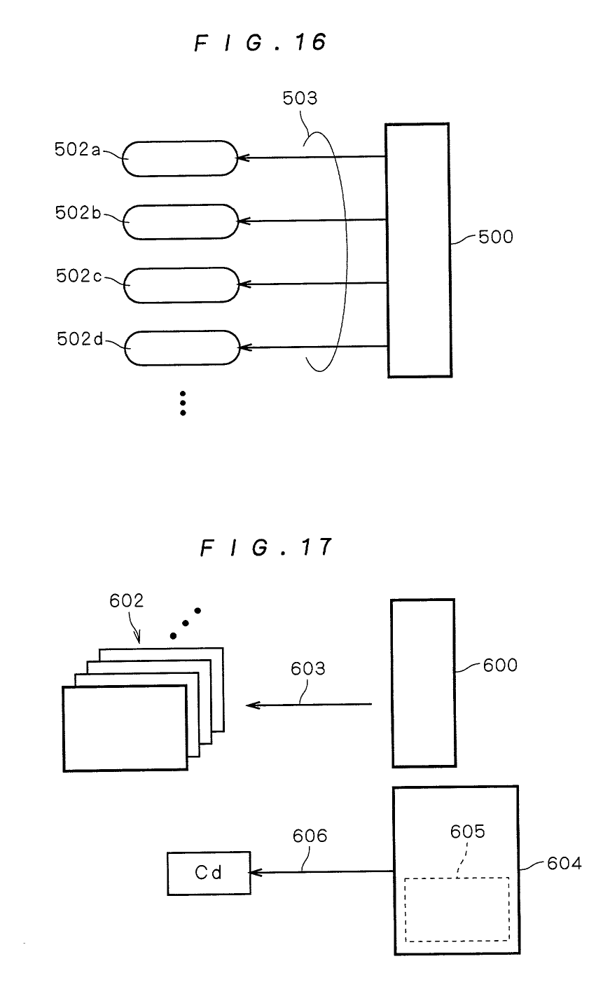

FIG. 16 is a conceptual view schematically illustrating the seventh preferred embodiment of the present invention. A lottery ticket issuer 500 issues a plurality of semiconductor elements 502a, 502b, 502c, 502d, . . . , which may be named as a selling act 503, for example. As described above, the semiconductor elements such as 502a, 502b, 502c and 502d each provide a unique identification code and therefore, they may be distinguishable thereamong. As a result, by separately setting a winning number, the selected one from the semiconductor elements 502a, 502b, 502c, 502d, . . . can be winning ticket.

The ticket issuer 500 is previously notified of the unique identification codes of the semiconductor elements 502a, 502b, 502c, 502d, . . . , among which a winning number may be selected. Alternatively, a winning number can be defined to be totally independent of the identification codes, resulting in the probability that no winning number can be found in the semiconductor elements 502a, 502b, 502c, 502d, and so forth available for the selling act 503. In this case, the prize accompanied by winning can be carried forward to the next lottery.

FIG. 17 is a conceptual view schematically illustrating the seventh preferred embodiment of the present invention in another phase. A lottery ticket issuer 600 issues a plurality of lottery tickets 602, which may be named as a selling act 603, for example. A winning number setting section 604 includes a semiconductor element 605 having a unique identification code Cd. The winning number setting section 604 makes the identification code Cd public, which may be called as publication 606. The identification code Cd as made open to the public is utilized as a winning code. It may be probable that no winning code can be found in the plurality of tickets 602 available for the selling act 603. In this case, the prize accompanied by winning can be carried forward to the next lottery.

Alternatively, the identification code of the semiconductor element 605 as illustrated in FIG. 17 is utilized as a winning code and the value of the lottery ticket may be determined on the basis of the degree of difference between the winning code and the identification code of each of the semiconductor elements such as 502a, 502b, 502c and 502d in FIG. 16 available as a ticket. More particularly, the semiconductor element 605 and each of the semiconductor elements 502a, 502b, 502c, 502d, . . . are compared in identification code per bit, for example. When the semiconductor element has the identification code including bits different from those of the winning code and the number of those different bits is not more than a predetermined value, it can be designated as a winning ticket. Further alternatively, a winning code may be naturally defined on the basis of the identification code of the semiconductor element 605.

The fourth through sixth preferred embodiments described so far and the seventh preferred embodiment do not necessarily require inclusion of polycrystalline semiconductor in a semiconductor element. The alternative type of a semiconductor element can be applicable as long as it has an identification code to be determined on the basis of variation in chemical structure such as impurity concentration as well as in microscopic structure such as crystal structure.

While the invention has been shown and described in detail, the foregoing description is in all aspects illustrative and not restrictive. It is therefore understood that numerous modifications and variations can be devised without departing from the scope of the invention.

What is claimed is:

1. A semiconductor integrated circuit, comprising:
a plurality of element pairs each including a first semiconductor element and a second semiconductor element,
wherein said first semiconductor element and said second semiconductor element are compared in electronic characteristic, a result of which being utilized for determining a binary logic for each of said plurality of element pairs.

2. The semiconductor integrated circuit according to claim 1,
wherein said first semiconductor element and said second semiconductor element are each a MOS transistor comprising a source electrode, a drain electrode and a gate electrode,
said source electrode of said first semiconductor element and said source electrode of said second semiconductor element receive a same potential of a predetermined value applied thereto, and
said first semiconductor element and said second semiconductor element are compared in characteristic of a drain current relative to a gate potential, a result of which being utilized for determining said binary logic for each of said plurality of element pairs.

3. The semiconductor integrated circuit according to claim 2, further comprising:
at least one word line connected to said gate electrode of said first semiconductor element and said gate electrode of said second semiconductor element in each of said plurality of element pairs.

4. The semiconductor integrated circuit according to claim 3,
wherein said at least one word line includes a plurality of word lines,
said drain electrodes of said first semiconductor elements connected to separate ones of said word lines are commonly connected to a first bit line,
said drain electrodes of said second semiconductor elements connected to separate ones of said plurality of word lines are commonly connected to a second bit line, and
said semiconductor integrated circuit further comprises at least one sense amplifier for comparing said first bit line and said second bit line in magnitude of current flowing therethrough.

5. The semiconductor integrated circuit according to claim 1,
wherein said first semiconductor element and said second semiconductor element are identical in macroscopic structure.

6. The semiconductor integrated circuit according to claim 5,
wherein said first semiconductor element and said second semiconductor element are isomorphic in said macroscopic structure.

7. The semiconductor integrated circuit according to claim 5,
wherein said first semiconductor element and said second semiconductor are each mirror image of the other in said macroscopic structure.

8. The semiconductor integrated circuit according to claim 5,
wherein said first semiconductor element and said second semiconductor element both include polycrystalline semiconductor.

9. The semiconductor integrated circuit according to claim 5,
wherein said first semiconductor element and said second semiconductor element both have impurity concentrations that randomly vary therebetween.

10. The semiconductor integrated circuit according to claim 1,
wherein said first semiconductor element and said second semiconductor element are each a MOS transistor, comprising:
a gate electrode having a planarized main surface;
a gate insulating film; and
a polycrystalline semiconductor layer including a channel region, a source region and a drain region, said polycrystalline semiconductor layer being opposed to said gate electrode through said gate insulating film with an area smaller than that of said main surface.

11. The semiconductor integrated circuit according to claim 2,
wherein said first semiconductor element and said second semiconductor element are each a MOS transistor, comprising:
a gate electrode having a planarized main surface;
a gate insulating film; and
a polycrystalline semiconductor layer including a channel region, a source region and a drain region, said polycrystalline semiconductor layer being opposed to said gate electrode through said gate insulating film with an area smaller than that of said main surface.

12. The semiconductor integrated circuit according to claim 5,
wherein said first semiconductor element and said second semiconductor element are each a MOS transistor, comprising:
a gate electrode having a planarized main surface;
a gate insulating film; and
a polycrystalline semiconductor layer including a channel region, a source region and a drain region, said polycrystalline semiconductor layer being opposed to said gate electrode through said gate insulating film with an area smaller than that of said main surface.

13. The semiconductor integrated circuit according to claim 1,
wherein said first semiconductor element and said second semiconductor element are each a MOS transistor comprising a channel region including polycrystalline semiconductor, and
at least one of a channel width and a channel length of said channel region has a value that is not less than the same as and not more than 10 times an average value of a diameter of a crystal grain in said polycrystalline semiconductor.

14. The semiconductor integrated circuit according to claim 2,
wherein said first semiconductor element and said second semiconductor element are each a MOS transistor comprising a channel region including polycrystalline semiconductor, and
at least one of a channel width and a channel length of said channel region has a value that is not less than the same as and not more than 10 times an average value of a [diameter of a crystal grain in said polycrystalline semiconductor.

15. The semiconductor integrated circuit according to claim 5,
wherein said first semiconductor element and said second semiconductor element are each a MOS transistor comprising a channel region including polycrystalline semiconductor, and
at least one of a channel width and a channel length of said channel region has a value that is not less than the same as and not more than 10 times an average value of a diameter of a crystal grain in said polycrystalline semiconductor.

16. The semiconductor integrated circuit according to claim 10,
wherein said channel region includes polycrystalline semiconductor, and
at least one of a channel width and a channel length of said channel region has a value that is not less than the same as and not more than 10 times an average value of a diameter of a crystal grain in said polycrystalline semiconductor.

17. A MOS transistor, comprising:
a gate electrode having a planarized main surface;
a gate insulating film; and
a polycrystalline semiconductor layer including a channel region, a source region and a drain region, said polycrystalline semiconductor layer being opposed to said gate electrode through said gate insulating film with an area smaller than that of said main surface.

18. A MOS transistor, comprising:
a source region;
a drain region; and
a channel region including polycrystalline semiconductor,
wherein at least one of a channel width and a channel length of said channel region has a value that is not less than the same as and not more than 10 times an average value of a diameter of a crystal grain in said polycrystalline semiconductor.
